(19) United States
(12) Patent Application Publication
(10) Pub. No.: US 2016/0336929 A1
(43) Pub. Date: Nov. 17, 2016

(54) COMPACT TRANSFORMER BASED REFLECTOR FOR EVEN FREQUENCY MULTIPLIERS

(71) Applicant: International Business Machines Corporation, Armonk, NY (US)

(72) Inventor: NADAV MAZOR, Givatayim (IL)

(21) Appl. No.: 14/709,520

(22) Filed: May 12, 2015

(51) Int. Cl. H03K 5/00

(52) U.S. Cl. CPC H03K 5/00006

(57) ABSTRACT

A system comprising: a frequency multiplier configured to receive an incoming RF signal having a fundamental frequency, and to output an outgoing RF signal having an output frequency that is an even multiple of the fundamental frequency; an input transformer comprising a multiplier-side inductor configured to provide the incoming RF signal, in a differential mode, to the frequency multiplier at the fundamental input frequency; a direct current bias source configured to bias the frequency multiplier, thereby producing the outgoing RF signal and multiple harmonic signals of the fundamental signal; and a reflector comprising a capacitor configured to resonate with the multiplier-side inductor at the output frequency, and reflect back a portion of the multiple harmonics signals having the output frequency back to the multiplier.

### BACKGROUND

The invention relates to the field of frequency multipliers.

Frequency multipliers are a basic building block in Radio Frequency Integrated Circuits (RFICs), such as are typically used in radio transceivers, imaging, and RADAR systems. However, most frequency multipliers have no conversion gain. To achieve a positive gain, a reflector is provided to reflect power back to the output signal.

However, such reflectors are typically unmatched to the input impedance, resulting in reflective loss at the input. To overcome this, additional components are typically added, which increase the cost and size of the chip, and which also introduce signal loss. Furthermore, increasing the number of components on the chip reduces the operative bandwidth of the chip and introduces processing errors resulting from non-compliance with the required tolerances.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, in accordance with an embodiment, a system comprising: a frequency multiplier configured to receive an incoming radio frequency signal having a fundamental frequency, and to output an outgoing radio frequency signal having an output frequency that is an even multiple of the fundamental frequency; an input transformer comprising a multiplier-side inductor configured to provide the incoming radio frequency signal, in a differential mode, to the frequency multiplier at the fundamental input frequency; a direct current bias source configured to bias the frequency multiplier, thereby producing the outgoing radio frequency signal and multiple harmonic signals of the fundamental signal; and a reflector comprising a capacitor configured to resonate with the multiplier-side inductor at the output frequency, and reflect back a portion of the multiple harmonics signals having the output frequency back to the multiplier.

In one embodiment, the direct current bias source is connected at a point of symmetry with respect to the multiplier-side inductor and the frequency multiplier.

In one embodiment, the multiplier-side inductor provides a radio frequency choke to the frequency multiplier.

In one embodiment, the capacitor is connected at a point of symmetry with respect to the multiplier-side inductor, thereby positioned at a virtual ground with respect to the incoming radio frequency signal.

In one embodiment, the reflector consists of the capacitor coupled to the multiplier-side inductor.

In one embodiment, the even multiple of the fundamental input frequency comprises twice the fundamental input frequency.

In one embodiment, the capacitor comprises a switch capacitor that is configured to resonate with the multiplier-side inductor at multiple different fundamental frequencies.

In one embodiment, an inductance Lₒᵤₜ of the multiplier-side inductor complies with:

Zᵢₙ=(zₒᵤₜN²∥jωLᵢₙk²)+jωLᵢₙ(1−k²)=Z_{source}*
wherein Zin is the impedance presented by the input transformer,
Zout is the impedance presented by the frequency multiplier,
Z_{source}* is the complex conjugate of a source impedance,
N is the turn ratio of the input transformer,
k is the coupling coefficient,
j is the imaginary unit, and
ω is the sinusoidal angular frequency.

In one embodiment, a capacitance of the capacitor C_{ref} is:

$${c}_{ref} = \frac{1}{{( 2 π {f}_{0} )}^{2} {L}_{out}}$$

where the fundamental frequency is f₀.

In one embodiment, the reflector is configured to attenuate an odd harmonic signal produced by the frequency multiplier.

There is provided, in accordance with an embodiment, a method comprising: coupling an incoming radio frequency signal having a fundamental input frequency through a multiplier-side inductor; providing the incoming radio frequency signal to a frequency multiplier in a differential mode; biasing the frequency multiplier to produce multiple harmonic signals of the fundamental signal comprising an outgoing radio frequency signal having an output frequency that is an even multiple of the fundamental frequency, resonating, via a capacitor coupled to the multiplier-side inductor, at the output frequency, thereby reflecting back a portion of the multiple harmonics signals having the output frequency; combining the reflected harmonics with the outgoing radio frequency signal; and outputting an outgoing radio frequency signal.

In one embodiment, the direct current bias source is connected at a point of symmetry with respect to the multiplier-side inductor and the frequency multiplier.

In one embodiment, the method further comprises providing a radio frequency choke to the frequency multiplier.

In one embodiment, the method further comprises providing a virtual ground to the incoming radio frequency signal, wherein the capacitor is positioned at the virtual ground.

In one embodiment, the reflector consists of the capacitor coupled to the multiplier-side inductor.

In one embodiment, the method further comprises the even multiple of the fundamental input frequency comprises twice the fundamental input frequency.

In one embodiment, the method further comprises the capacitor comprises a switch capacitor that is configured to resonate with the multiplier-side inductor at multiple different fundamental frequencies.

In one embodiment, the method further comprises an inductance Lₒᵤₜ of the multiplier-side inductor complies with:

Zᵢₙ=(zₒᵤₜN²∥jωLᵢₙk²)+jωLᵢₙ(1−k²)=Z_{source}*
wherein Zin is the impedance presented by the input transformer,
Zout is the impedance presented by the frequency multiplier,
Z_{source}* is the complex conjugate of a source impedance,
N is the turn ratio of the input transformer,
k is the coupling coefficient,
j is the imaginary unit, and
ω is the sinusoidal angular frequency.

In one embodiment, a capacitance of the capacitor C_{ref} is:

$${c}_{ref} = \frac{1}{{( 2 π {f}_{0} )}^{2} {L}_{out}}$$

where the fundamental frequency is f₀.

In one embodiment, the method further comprises attenuating an odd harmonic signal produced by the frequency multiplier.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1 illustrates a circuit configured to provide a compact, high gain frequency multiplier design, in accordance with an embodiment;

FIGS. 2A-C illustrate an analysis of input transformer of FIG. 1, in accordance with an embodiment;

FIGS. 3A-C show an analysis of the reflector of FIG. 1, in accordance with an embodiment;

FIGS. 4A-F show several conceptual illustrations of the reflector of FIG. 1 configured with different common emitter (CE) bipolar even multipliers, in accordance with an embodiment;

FIGS. 5A-F show several conceptual illustrations of the reflector of FIG. 1 configured with different common base (CB) bipolar even multipliers, in accordance with different embodiments;

FIGS. 6A-F show several conceptual illustrations of the reflector of FIG. 1 configured with different common source (CS) MOSFET (Metal Oxide Semiconductor Field-Effect Transistor) even multipliers, in accordance with different embodiments;

FIGS. 7A-F show several conceptual illustrations of the reflector of FIG. 1 configured with different common gate (CG) MOSFET even multipliers, in accordance with different embodiments; and

FIG. 8 illustrates a flowchart of a method associated with the system of FIG. 1, in accordance with an embodiment.

### DETAILED DESCRIPTION

A system and method are described herein to provide a compact, high gain reflector for use with a frequency multiplier. The reflector comprises a capacitor that is symmetrically positioned with respect to an inductor of an impedance-matched input transformer, and configured to resonate with the inductor at the desired output frequency. This serves to capture and reflect back a common mode signal that would otherwise be lost, such as the desired even harmonic signals. The symmetry of the design provides a virtual ground to isolate the reflector to differential mode signals, such as the input signal and any undesired odd harmonic signals.

The reflector disclosed herein may be used for incoming signals having frequencies spanning from X-band range of 8-12 GigaHertz (GHz) up to the millimeter-wave range, reaching as high as 300 GHz. In other embodiments, incoming signals may have lower or higher frequencies than the aforementioned range.

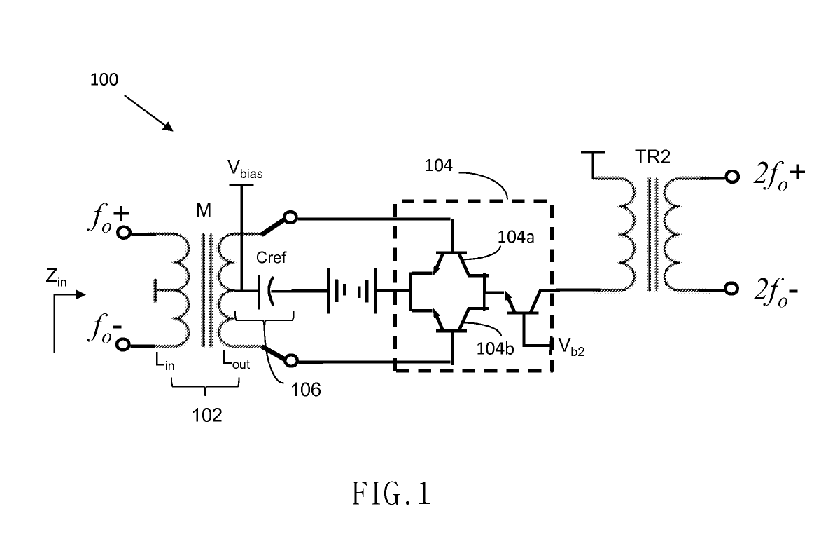

Reference is now made to FIG. 1 which illustrates a circuit 100 configured to provide a compact, high gain frequency multiplier design, in accordance with an embodiment. Circuit 100 includes an input transformer 102 comprising an input-side inductor Lᵢₙ coupled to a multiplier-side inductor Lₒᵤₜ that is configured to provide an incoming radio frequency (RF) signal having a fundamental input frequency f₀, in a differential mode, to a frequency multiplier 104. Multiplier 104 is configured to receive the incoming (RF) signal, and output an outgoing RF signal having an output frequency that is an even multiple of f₀. Inductors Lᵢₙ and Lₒᵤₜ may be configured to provide input transformer 102 with an impedance Zᵢₙ that matches a source impedance presented by a the source of the incoming RF signal and thereby reduce reflective loss at the input of circuit 100 due to mismatched impedances.

Frequency multiplier 104 may comprise any suitable even multiplier. For example, in the non-limiting illustration of FIG. 1A, multiplier 104 is shown having two bipolar transistors 104a and 104b arranged symmetrically opposed to each other that receive the incoming RF signal via their respective bases, and transmit the outgoing signal via their respective collectors. Although the foregoing non-limiting description will refer hereon to generating an output signal having a frequency of 2f₀, this is for simplicity only and it is understood that the reflector may be configured for any even multiple of the fundamental frequency f₀.

A direct current (DC) bias source V_{bias} is provided at a central tap to bias transistors 104a and 104b, comprising frequency multiplier 104, and produce the outgoing RF signal at the desired output frequency, as well as multiple harmonic signals k*f₀ for k=2, 3, 4 . . . of the fundamental signal f₀. V_{bias} may be selected to optimally bias transistors 104a and 104b and may be provided at the central tap as a virtual ground for the incoming RF signal. A typical value for V_{bias} applied to bipolar transistors may range from 0.6 volts (V) to 0.9V, covering known class B and class A biasing modes.

V_{bias} is connected at a point of symmetry with respect to Lₒᵤₜ and therefore, does not affect the incoming RF signal that is coupled through Lₒᵤₜ in differential mode. To multiplier 104. Referring to FIG. 1, V_{bias} is connected to the midpoint of Lₒᵤₜ and provides biasing to each of the bases of transistors 104a and 104b. This symmetry provided by Lₒᵤₜ is utilized by transistors 104a and 104b as an ‘RF choke’, serving to separate between the incoming RF signal and the DC bias feed. Thus, the RF signal entering the transistors 104a and 104b is augmented by the DC bias voltage without affecting the frequency or phase of the RF signal. V_{bias} may be selected for high output current on the desired even harmonic. The non-linear distortion required to produce the multiple harmonics may be generated either from the natural transfer function of transistors 104a and 104b, for example a bipolar junction transfer exponential, or via a nonlinear working mode, such as class B, class AB, or any other suitable bias that may clip the output signal, to produce signal components having integer multiples of the fundamental input frequency f₀, such as are represented by Fourier components having frequencies kf₀ for k=2,3,4 . . .

For example, the characteristics of V_{bias} may be selected to push transistors 104a and 104b into a class-a mode of operation and drive a relatively high current for signal components having the frequency 2f₀. In another mode of operation, V_{bias} may be selected to push transistors 104a and 104b to produce a high desired harmonic signal relative to the fundamental output signal.

At least one of the components produced by frequency multiplier 104, as driven by V_{bias}, is the desired multiplied output RF signal having a frequency of 2f₀. This desired output signal and any desired reflected even harmonic signals may be tapped out of multiplier 104 as the outgoing RF signal, such as by using a wire. The output signal may be sent through an additional transformer balun TR2 to create an output differential signal.

However, another portion of this desired even harmonic multiple RF output signal is leaked back in common mode, together with the other harmonics produced by distorting the incoming RF signal. Additionally, a portion of the odd harmonic multiple RF output signal is leaked back in differential mode This common mode portion of the signal having the desired output frequency 2f₀ would typically be lost.

A reflector 106, comprising a capacitor C_{ref}, is connected at a point of symmetry with respect to Lₒᵤₜ that provides a virtual ground for the incoming differential RF signal. C_{ref} is positioned is configured to resonate with Lₒᵤₜ to create a ‘short’ at the desired output frequency 2f₀, and thereby capture and reflect back a portion of the multiple harmonics signals having the output frequency back to multiplier 104. C_{ref} is configured to reflect the common mode, even harmonic components back to frequency multiplier 104, whereas the differential mode, odd harmonic components are not affected by C_{ref} and are attenuated due to their phase. Thus, this common mode reflected portion of the signal is transferred back to multiplier 104 and combined with the outgoing RF signal to improve the gain of frequency multiplier 104.

By utilizing Lₒᵤₜ of input transformer 102 to couple with C_{ref} and resonate at the desired output frequency, in one embodiment, reflector 106 may consist of only Lₒᵤₜ coupled to C_{ref}, and thus, since Lₒᵤₜ comprises an intrinsic component of input transformer 102, the only additional component required to implement reflector 106 and improve the gain of multiplier 104 is C_{ref} resulting in a compact, cost effective design that avoids unwanted effects from additional components, such as inductors that introduce loss and could create undesired magnetic coupling.

Additionally, due to the preservation of phase by reflector 106, any other common mode signals having even frequency multiples 2_{kf0} for k=2,3,4 . . . constructively interfere with the resonating 2f₀ common mode component, and are at least partially captured and reflected back to frequency multiplier 104, while the desired even multiple is fully reflected. Conversely, any odd harmonic components produced by multiplier 104, such as having the fundamental frequency, destructively interfere in reflector 106, and are attenuated.

Advantageously, the symmetric configuration of the reflector, comprising Lₒᵤₜ coupled with C_{ref}, and V_{bias} with respect to multiplier 104 precludes any effect by V_{bias} and/or the reflector on the incoming differential signal, As stated above, the reflector is only sensitive to common mode signals. Furthermore, C_{ref} is positioned at a virtual ground with respect to the incoming differential RF signal.

Thus, V_{bias} may be selected according to the intrinsic properties of multiplier 104 to produce the desired output signal at 2f₀. Lᵢₙ and Lₒᵤₜ may be selected to have a combined impedance Zᵢₙ that matches the source impedance, such as may be produces by an earlier stage, to reduce reflective loss at the input. C_{ref} may be selected to resonate with Lₒᵤₜ at 2f₀.

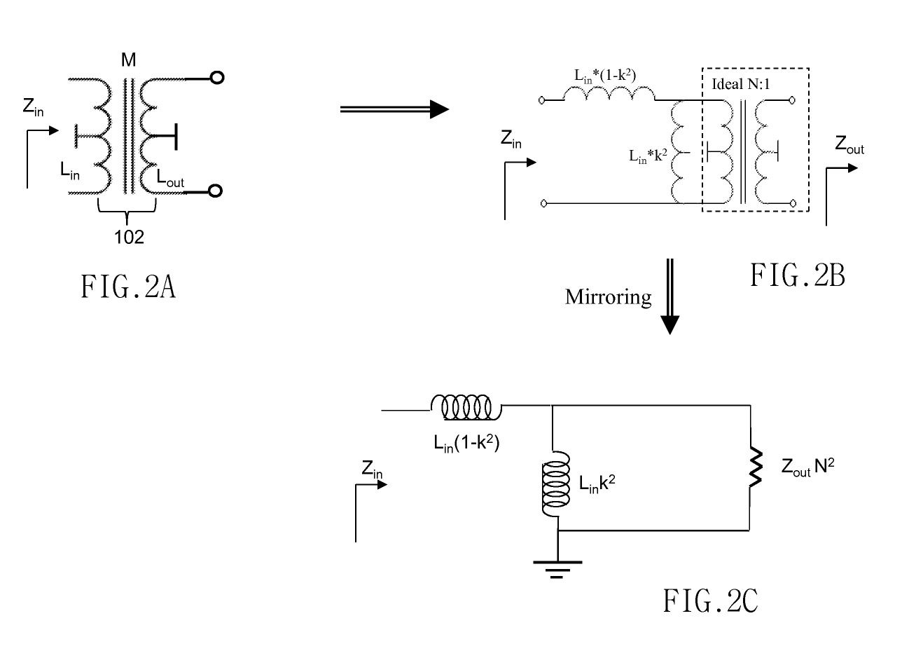

Reference is now made to FIGS. 2A-C which together illustrate an analysis of input transformer 102, in accordance with an embodiment. Referring to FIG. 2A, a simplified conceptual illustration of input transformer 102 is shown, with the input-side inductor Lᵢₙ having inductance Lᵢₙ, and the multiplier-side inductor Lₒᵤₜ having inductance Lₒᵤₜ. The ratio between the number of turns on each inductor Lᵢₙ and Lₒᵤₜ, represented by N, and the coefficient of coupling k, are given by the following equations:

$$N = \frac{1}{k} \sqrt{\frac{{L}_{in}}{{L}_{out}}} \\ k = \frac{M}{\sqrt{{L}_{in} {L}_{out}}} \qquad ( 1 )$$

where M is the mutual inductance.

Referring to FIGS. 2B-C, transformer 102 may be represented as a T-equivalent circuit with non-coupled inductors having inductance Lᵢₙ*(1−k²) and Lᵢₙ*k² followed by an ideal transformer, where the input impedance is given as:

Zin=(ZₒᵤₜN²∥jωLᵢₙk²)+jωLᵢₙ(1−k²) (2)

For imaginary unit j, and sinusoidal angular frequency ω, and where the output impedance Zₒᵤₜ may be represented by an impedance having a value of Zₒᵤₜ*N². Zᵢₙ represents the impedance presented by transformer 102 and Zₒᵤₜ represents the impedance presented by multiplier 104 and which may be determined from the intrinsic properties of transistors 104a and 104b. Thus, input transformer 102 may be selected to provide an impedance, Zᵢₙ, that matches a source impedance Z_{source} corresponding to a previous stage to circuit 100 that introduces incoming RF signal to circuit 100, and thus equivalent to the complex conjugate of Z_{source}, or Z_{source}*. Using equations (1) and (2) above, the values for Lᵢₙ and Lₒᵤₜ, N and k comprising input transformer 102 may be determined from Z_{source} and Zₒᵤₜ. Furthermore, since Zₒᵤₜ is determined as the impedance of multiplier 104, Zₒᵤₜ is significant only to differential signals, and is therefore ‘blind’ or not affected by capacitor C_{ref}.

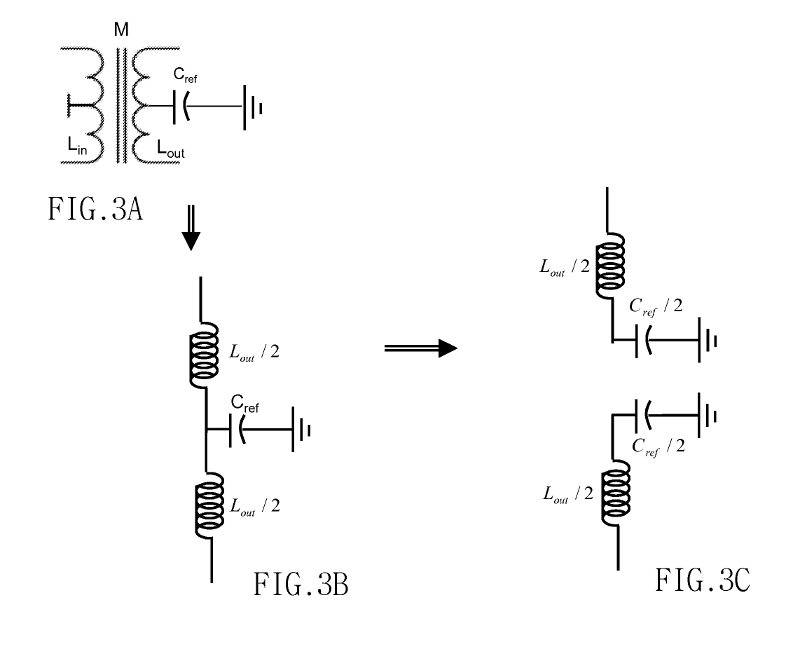

Reference is now made to FIGS. 3A-C which illustrate an analysis of the reflector of FIG. 1, in accordance with an embodiment. Referring to FIG. 3A, the reflector comprises capacitor C_{ref} symmetrically positioned with respect to inductor Lₒᵤₜ. FIGS. 3B-C illustrate equivalent arrangements for the reflector of FIG. 3A using conventional techniques. Using the symmetry illustrated by FIGS. 3B-C, C_{ref} may be selected to resonate with inductor Lₒᵤₜ at 2fas follows

$$2 {f}_{0} = \frac{1}{2 π \sqrt{\frac{{C}_{ref} {L}_{out}}{4}}} \to {c}_{ref} = \frac{1}{{( 2 π {f}_{0} )}^{2} {L}_{out}} \qquad ( 3 )$$

Thus, for a given value of Lₒᵤₜ calculated above, and a fundamental input frequency f₀, C_{ref} may be determined, accordingly.

The following sequential steps describe an exemplary method for determining one or more components of the reflector of FIG. 1.
a) Select the transistor pair, comprising the multiplier, and the corresponding bias to maximize the output current at the desired even harmonic;
b) Measure the input impedance of the transistor pair (Zout);
c) Choose transformer parameters—Lᵢₙ, Lₒᵤₜ, and k to correspond to the impedance presented by the frequency multiplier and the source impedance, by matching the input impedance with the source impedance Zs, where Zs* is the complementary source impedance. Thus, the inductance Lₒᵤₜ complies with:

Zin=(ZₒᵤₜN²∥jωLᵢₙk²)+jωLᵢₙ(1−k²)=Zs*
d) Having determined Lout, for a desired even harmonic of the fundamental frequency, choose Cref:

$$2 {f}_{0} = \frac{1}{2 π \sqrt{\frac{{C}_{ref} {L}_{out}}{4}}} \to {c}_{ref} = \frac{1}{{( 2 π {f}_{0} )}^{2} {L}_{out}}$$

As is evident from the symmetry of the design described above, the incoming differential signal at f₀ is evenly distributed for input into transistors 104a and 104b of multiplier 104, and the direction of the incoming differential current oscillates in accordance with the reversing the polarity of the incoming signal. The symmetric positioning of C_{ref} with respect to Lₒᵤₜ and the central tap V_{bias} provides a virtual ground for multiplier 104, making C_{ref} effectively invisible to the incoming differential signal. Similarly, V_{bias} as a DC supply does not affect the incoming differential signal, but merely pushes multiplier 104 to a state that produces higher harmonics of the incoming signal.

Thus the componentry added as part of the reflector of the circuit, namely C_{ref} coupled to Lₒᵤₜ, are passive components that do not affect the incoming differential signal, and are compact, thus occupy only a small portion of the circuit.

However, since C_{ref} is coupled to Lₒᵤₜ to resonate at 2f₀, together they capture any common mode signals having even multiples of f₀ that may have leaked from transistors 104a and 104b, such as due to any non-linear properties of transistors 104a and 104b. These captured common mode signals are added to and reflected back with the outgoing signal, while the desired harmonic is completely reflected due to the selection of the Cref, thereby improving the performance of multiplier 104 and increasing its gain. Furthermore, Cref is invisible to any differential mode signals, such as comprising any signal leakage by transistors 104a and 104b having odd multiples of f₀ and resulting in their attenuation.

V_{bias} may be selected in accordance with the properties of transistor 104a and 104b to provide a relatively high current, or gain, in the second harmonic, 2f₀. Thus, any leaked signal may be amplified, and signal components with even multiples of f₀ may be captured and reflected back to the output.

Furthermore, the modality of the signals is preserved. Thus, common mode signals with even multiples of f₀ are added via constructive interference, wherein the differential mode signals with odd multiples of f₀ cancel each other out via destructive interference.

Optionally, C_{ref} may comprise a switch capacitor that is configured to resonate with Lₒᵤₜ at multiple different fundamental frequencies, and allowing circuit 100 to multiply signals having multiple different fundamental frequencies f₀.

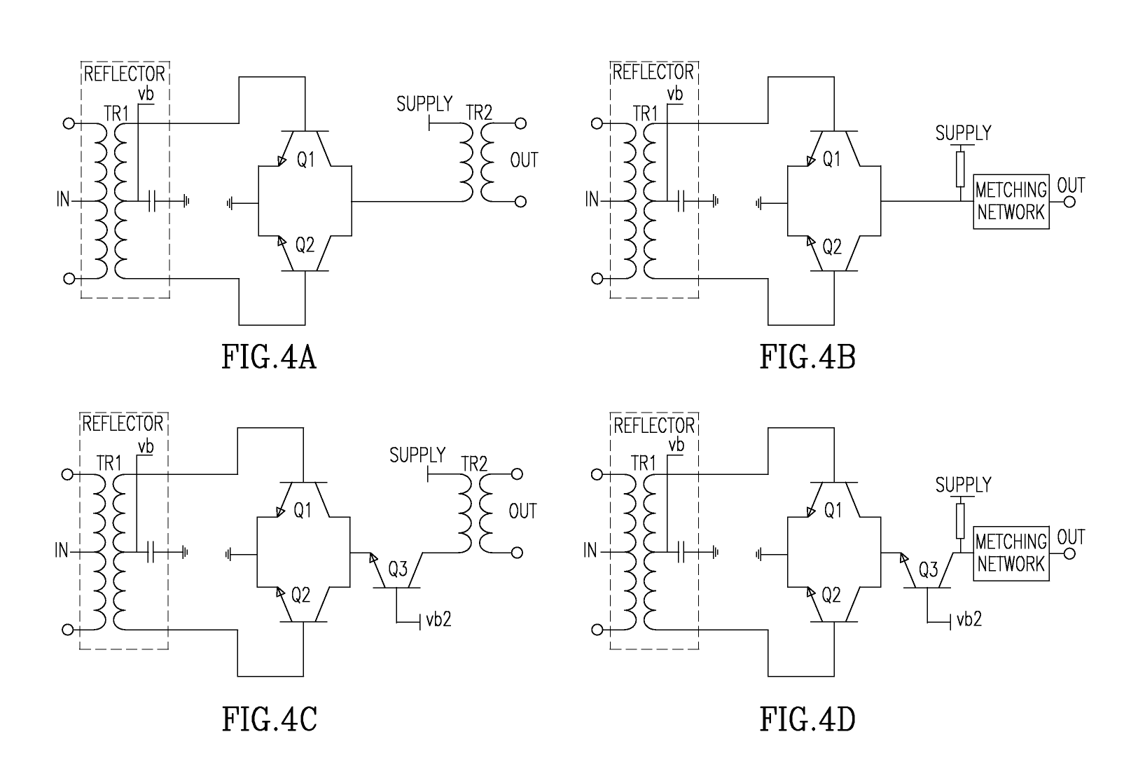

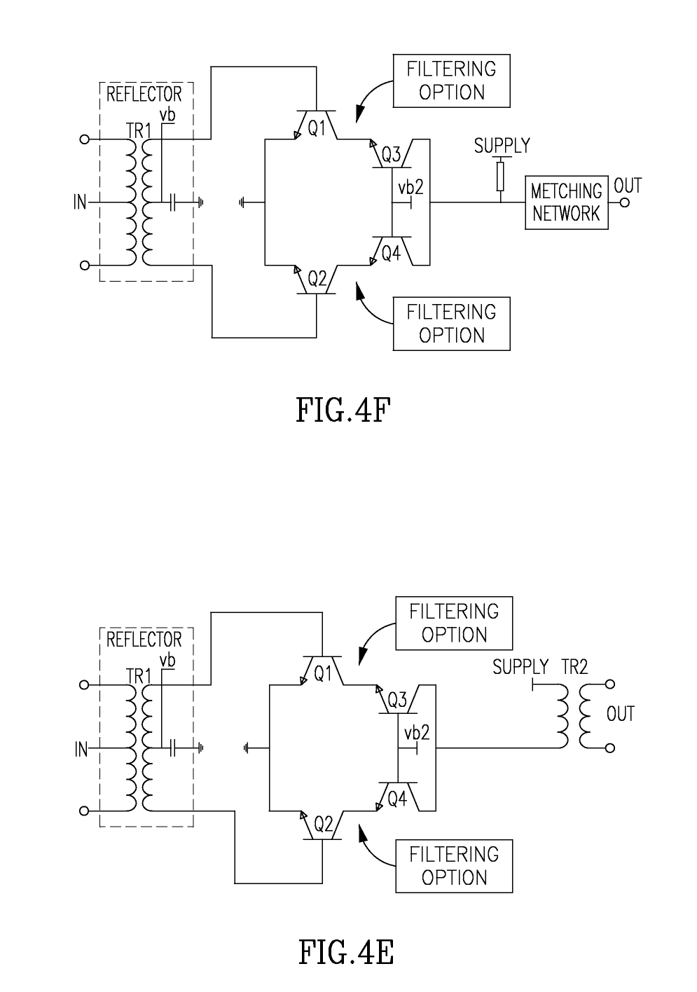

The reflector described above may be configured with any suitable multiplier circuit configuration. For example, referring to FIGS. 4A-F, several conceptual illustrations of the reflector of FIG. 1 configured with different common emitter (CE) bipolar even multipliers are shown, in accordance with different embodiments. In these configurations, the differential incoming signal and V_{bias} are fed into the base of each of the transistors, Q1 and Q2.

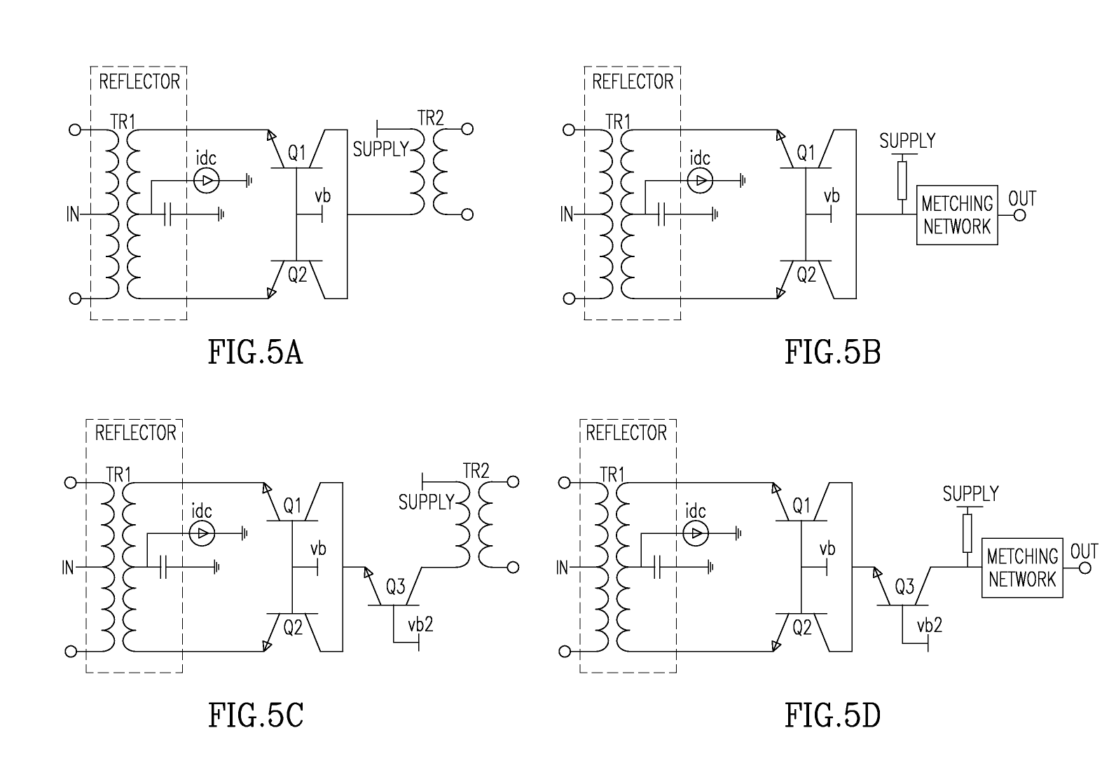

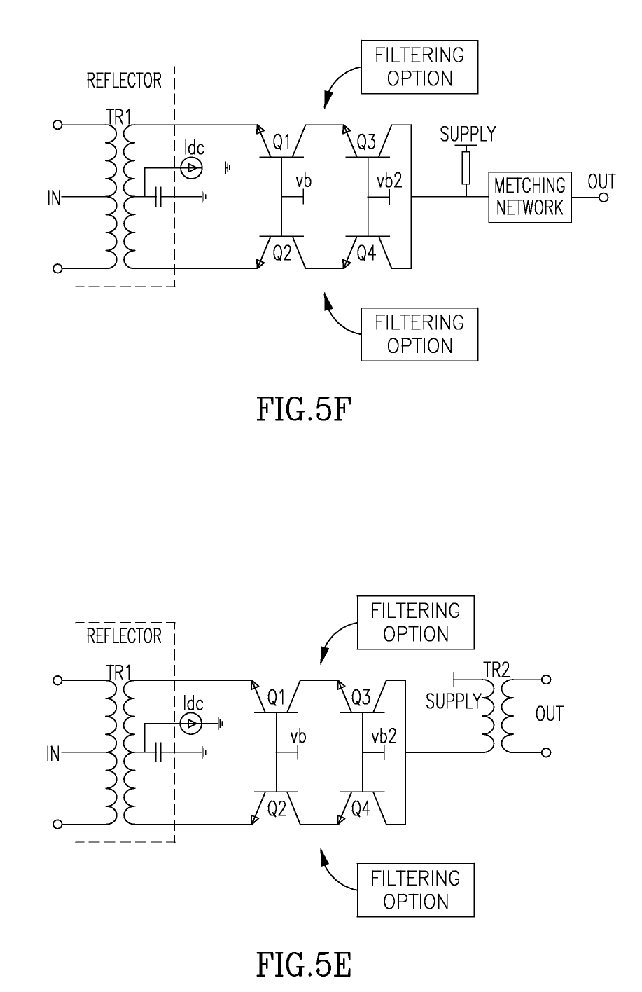

FIGS. 5A-F show several conceptual illustrations of the reflector of FIG. 1 configured with different common base (CB) bipolar even multipliers, in accordance with different embodiments. In these configurations, the differential incoming signal and DC current are fed into the emitter of each of the transistors Q1 and Q2, while V_{bias} is fed into their respective bases.

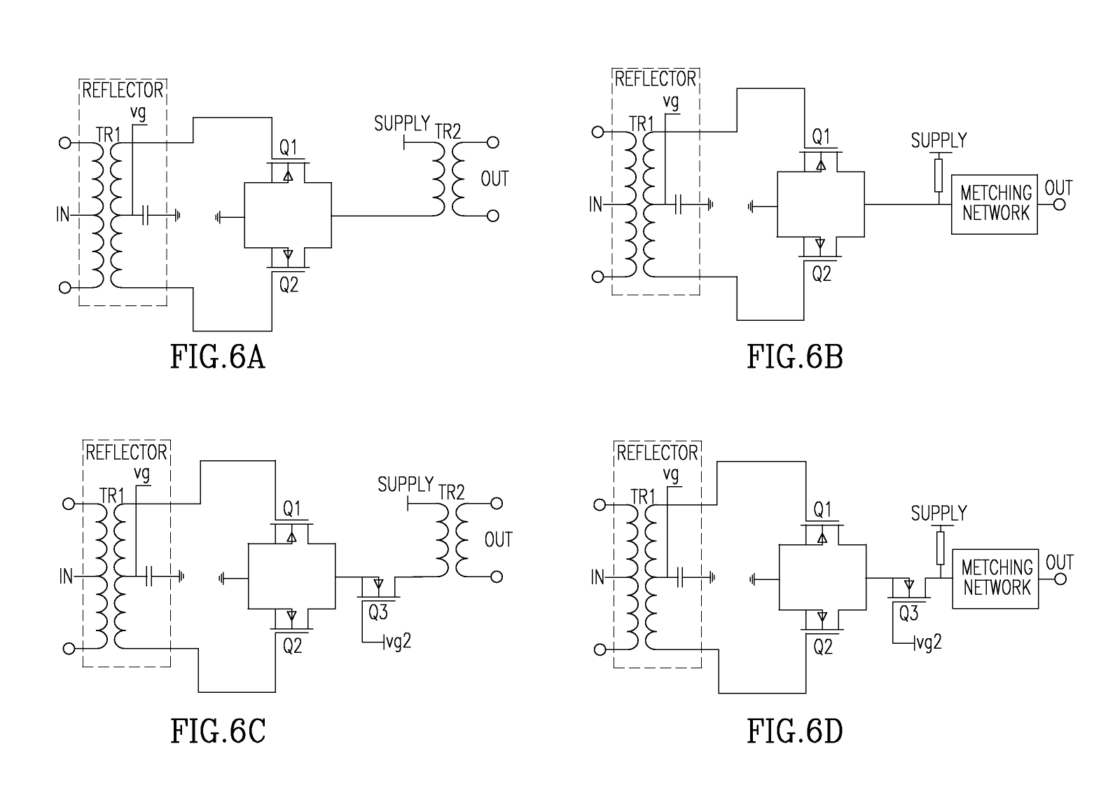

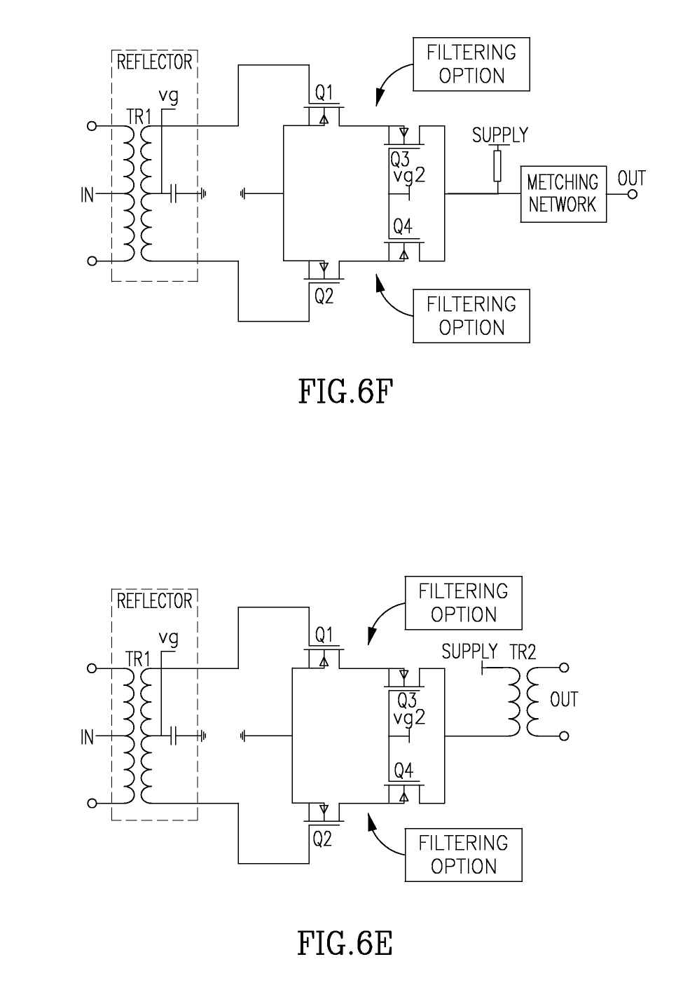

FIGS. 6A-F show several conceptual illustrations of the reflector of FIG. 1 configured with different common source (CS) MOSFET even multipliers, in accordance with different embodiments. In these configurations, the differential incoming signal and V_{bias} are fed into the gates each of the transistors Q1 and Q2.

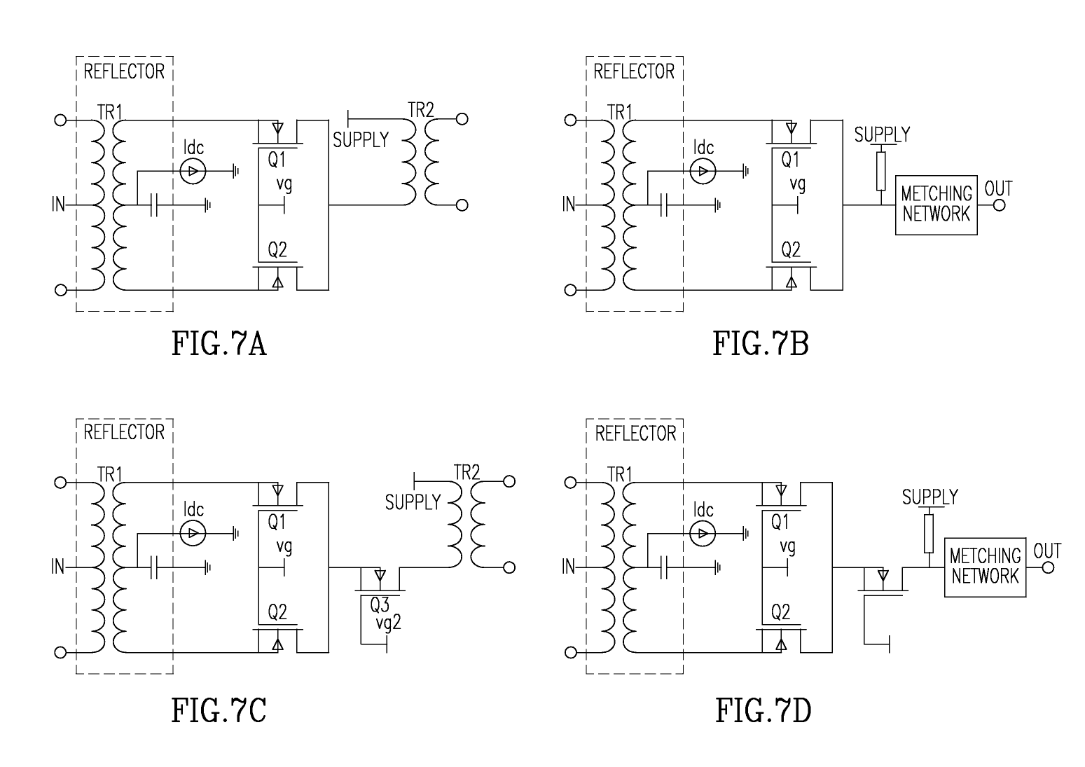

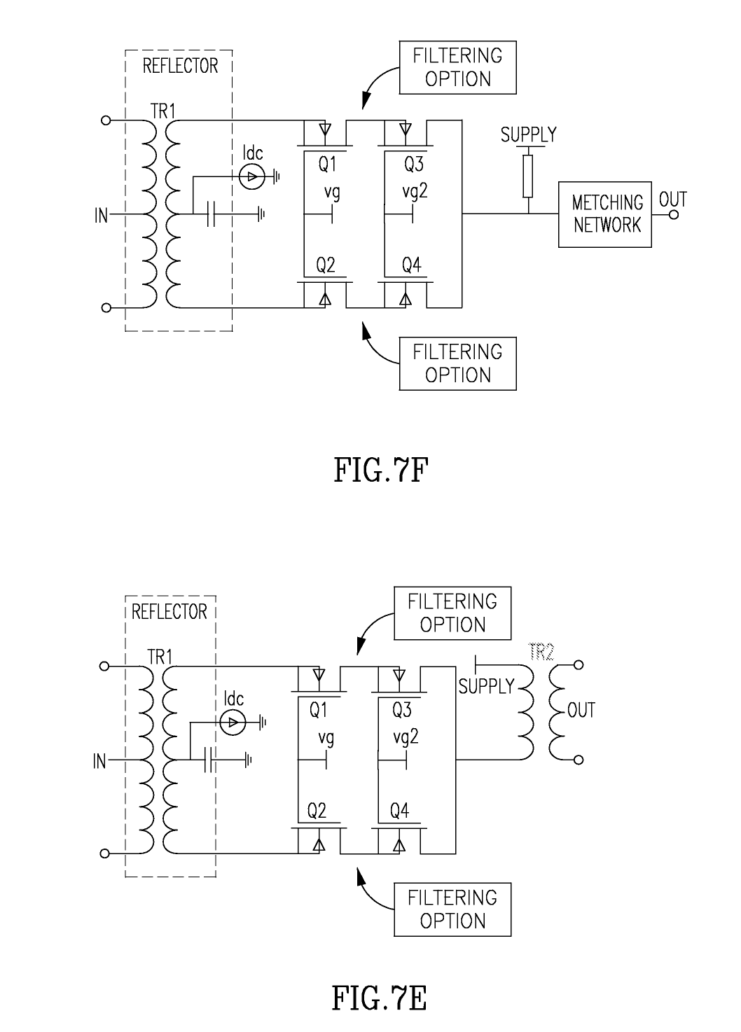

FIGS. 7A-F show several conceptual illustrations of the reflector of FIG. 1 configured with different common gate (CG) MOSFET even multipliers, in accordance with different embodiments. In these configurations, the differential incoming signal and DC current is fed into the source of each of the transistors Q1 and Q2, while V_{bias} is fed into the respective gate of each of the transistors, Q1 and Q2.

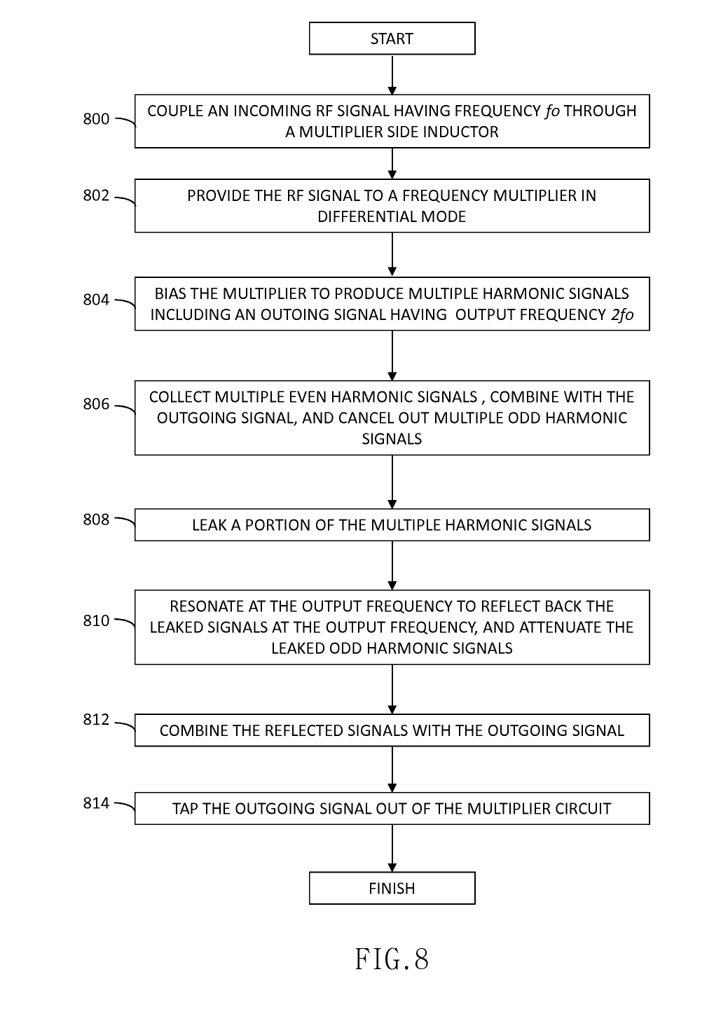

Reference is now made to FIG. 8 which shows a flowchart of a method associated with the system of FIG. 1, in accordance with an embodiment.

An input transformer comprising a multiplier-side inductor coupled to an input-side inductor is provided to present an impedance Zᵢₙ that matches a source impedance of a source that provides an incoming RF signal having a fundamental input frequency f₀. The incoming RF signal is coupled through the multiplier-side inductor (Step 800). The incoming radio frequency signal is provided to a frequency multiplier in a differential mode (Step 802).

A DC bias source may bias the multiplier into a mode that produces multiple harmonics of f₀, including an outgoing radio frequency signal having an output frequency that is an even multiple of the fundamental frequency, such as by pushing multiple transistors comprising the multiplier into class-a, class-b, or class-ab mode of operation to drive a current flow (Step 804). The multiple harmonics may additionally include odd harmonic signals in negative phase, and even harmonic signals that are in phase.

The multiple signals produced by the multiplier are collected and the odd harmonic signals are canceled, and the even harmonic signals are combined and added to the outgoing RF signal having frequency 2f₀ (Step 806). A portion of the harmonic signals produced is leaked to the input transformer, were the even harmonic signals are leaked in common mode, and the odd harmonic signals are leaked in differential mode (Step 808).

A capacitor coupled to and symmetrically positioned with respect to the multiplier-side inductor resonates at the output frequency, thereby reflecting back the portion of the multiple harmonics signals having the output frequency, and attenuating the odd harmonic signals (Step 810). The reflected harmonics are combined with the outgoing signal to contribute to the output conversion gain (Step 812). The outgoing signal is tapped out of the multiplier circuit (Step 814).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the market site, or to enable others of ordinary skill in the art to understand the embodiments disclosed herein.

What is claimed is:

1. A system comprising:
a frequency multiplier configured to receive an incoming radio frequency signal having a fundamental frequency, and to output an outgoing radio frequency signal having an output frequency that is an even multiple of the fundamental frequency;
an input transformer comprising a multiplier-side inductor configured to provide the incoming radio frequency signal, in a differential mode, to the frequency multiplier at the fundamental input frequency;
a direct current bias source configured to bias the frequency multiplier, thereby producing the outgoing radio frequency signal and multiple harmonic signals of the fundamental signal; and
a reflector comprising a capacitor configured to resonate with the multiplier-side inductor at the output frequency, and reflect back a portion of the multiple harmonics signals having the output frequency back to the multiplier.

2. The system of claim 1, wherein the direct current bias source is connected at a point of symmetry with respect to the multiplier-side inductor and the frequency multiplier.

3. The system of claim 2, wherein the multiplier-side inductor is configured to provide a radio frequency choke to the frequency multiplier.

4. The system of claim 1, wherein the capacitor is connected at a point of symmetry with respect to the multiplier-side inductor, thereby positioned at a virtual ground with respect to the incoming radio frequency signal.

5. The system of claim 1, wherein the reflector consists of the capacitor coupled to the multiplier-side inductor.

6. The system of claim 1, wherein the even multiple of the fundamental input frequency comprises twice the fundamental input frequency.

7. The system of claim 1, wherein the capacitor comprises a switch capacitor that is configured to resonate with the multiplier-side inductor at multiple different fundamental frequencies.

8. The system of claim 1, wherein an inductance (Lₒᵤₜ) of the multiplier-side inductor complies with:
Zᵢₙ=(zₒᵤₜN²∥jωLᵢₙk²)+jωLᵢₙ(1−k²)=Z_{source}*,
where Zᵢₙ is the impedance presented by the input transformer,
Zₒᵤₜ is the impedance presented by the frequency multiplier,
Z_{source}* is the complex conjugate of a source impedance,
N is the turn ratio of the input transformer,
k is the coupling coefficient,
j is the imaginary unit, and
ω is the sinusoidal angular frequency.

9. The system of claim 8, wherein a capacitance of the capacitor (C_{ref}) is:
$${c}_{ref} = \frac{1}{{( 2 π {f}_{0} )}^{2} {L}_{out}} ,$$
where the fundamental frequency is f₀.

10. The system of claim 1, wherein the reflector is configured to attenuate an odd harmonic signal produced by the frequency multiplier.

11. A method comprising:
coupling an incoming radio frequency signal having a fundamental input frequency through a multiplier-side inductor;
providing the incoming radio frequency signal to a frequency multiplier in a differential mode;
biasing the frequency multiplier to produce multiple harmonic signals of the fundamental signal comprising an outgoing radio frequency signal having an output frequency that is an even multiple of the fundamental frequency,
resonating, via a capacitor coupled to the multiplier-side inductor, at the output frequency, thereby reflecting back a portion of the multiple harmonics signals having the output frequency;
combining the reflected harmonics with the outgoing radio frequency signal; and
outputting an outgoing radio frequency signal.

12. The method of claim 11, wherein the direct current bias source is connected at a point of symmetry with respect to the multiplier-side inductor and the frequency multiplier.

13. The method of claim 12, further comprising providing a radio frequency choke to the frequency multiplier.

14. The method of claim 11, further comprising providing a virtual ground to the incoming radio frequency signal, wherein the capacitor is positioned at the virtual ground.

15. The method of claim 11, wherein the reflector consists of the capacitor coupled to the multiplier-side inductor.

16. The method of claim 11, wherein the even multiple of the fundamental input frequency comprises twice the fundamental input frequency.

17. The method of claim 11, wherein the capacitor comprises a switch capacitor that is configured to resonate with the multiplier-side inductor at multiple different fundamental frequencies.

18. The method of claim 11, wherein an inductance (Lₒᵤₜ) of the multiplier-side inductor complies with:
Zᵢₙ=(zₒᵤₜN²∥jωLᵢₙk²)+jωLᵢₙ(1−k²)=Z_{source}*,
where Zᵢₙ is the impedance presented by the input transformer,
Zₒᵤₜ is the impedance presented by the frequency multiplier,
Z_{source}* is the complex conjugate of a source impedance,
N is the turn ratio of the input transformer,
k is the coupling coefficient,
j is the imaginary unit, and
ω is the sinusoidal angular frequency.

19. The method of claim 18, wherein a capacitance of the capacitor (C_{ref}) is:
$${c}_{ref} = \frac{1}{{( 2 π {f}_{0} )}^{2} {L}_{out}}$$
where the fundamental frequency is f₀.

20. The method of claim 11, further comprising attenuating an odd harmonic signal produced by the frequency multiplier.
